(19) United States
(12) Patent Application Publication
(10) Pub. No.: US 2006/0019473 A1
(43) Pub. Date: Jan. 26, 2006

(54) Method of crystallizing amorphous Si film

(75) Inventor: Chei-jong Choi, Gyeonggi-do (KR)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Samsung Electronics Co., Ltd., Gyeonggi-do (KR)

(21) Appl. No.: 11/139,445

(22) Filed: May 31, 2005

(30) Foreign Application Priority Data
Jul. 21, 2004 (KR) 10-2004-0056818

(51) Int. Cl. H01L 21/20

(52) U.S. Cl. 438/486; 438/487

(57) ABSTRACT

A method of crystallizing an amorphous Si film is provided. The method of crystallizing an amorphous Si film may include doping the amorphous Si film formed on a substrate with predetermined metal ions, and annealing the amorphous Si film doped with the metal ions to crystallize the amorphous Si film. According to the method of crystallizing an amorphous Si film, the amorphous Si film can be crystallized with lower energy and the surface roughness of a crystallized Si film can be improved.

### BACKGROUND

This application claims the benefit of Korean Patent Application No. 10-2004-0056818, filed on Jul. 21, 2004, in the Korean Intellectual Property Office, the disclosure of which is incorporated herein in its entirety by reference.

1. Field of the Invention

An embodiment of the present invention relates to a method of crystallizing an amorphous Si film, and more particularly, to a method of crystallizing an amorphous Si film with low energy, thereby improving the surface roughness of a crystallized Si film.

2. Description of the Related Art

U.S. Pat. No. 4,406,709 and U.S. Pat. No. 4,309,225 disclose a method of crystallizing an amorphous Si film.

According to a conventional method of crystallizing an amorphous Si film, an amorphous Si film was molten momentarily by irradiating a strong laser beam onto the surface of the amorphous Si film and the molten amorphous Si film was cooled again, thereby preparing a crystallized Si film with a thickness of tens μm.

However, in the case of this method, since the size of Si grain crystallized is determined by the magnitude of laser beam energy, a laser beam of high energy is required to form Si crystals having a smaller grain size.

Also, the surface roughness of crystallized Si film is deteriorated due to the use of a laser beam of high energy.

Recently, U.S. Pat. No. 6,479,329 B2 provides a method of using a crystallization catalyst material with a laser annealing in order to crystallize an amorphous Si film with laser beam of low energy.

U.S. Pat. No. 6,479,329 B2 reports that when an annealing process is performed after forming a Ni-silicide layer on an amorphous Si film through spin coating and patterning the Ni-silicide layer, crystallization of the amorphous Si film occurs in a portion where the Ni-silicide is placed. In this case, the Ni-silicide is used as a catalyst material.

However, in the case of this method, there is a considerable amount of Ni-silicide in the crystallized portion and crystallization occurs only on a surface portion contacting the Ni-silicide.

### SUMMARY

An embodiment of the present invention provides a method of crystallizing an amorphous Si film with low energy, thereby improving the surface roughness of the Si film crystallized.

According to an aspect of the present invention, there is provided a method of crystallizing an amorphous Si film, the method including: doping the amorphous Si film formed on a substrate with predetermined metal ions; and annealing the amorphous Si film doped with metal ions to crystallize the amorphous Si film.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1C are a process flow chart of a method of crystallizing an amorphous Si film according to the present invention;

FIGS. 2A and 2B are transmission electron microscope (TEM) photographs of cross-sectionals of a sample with Ni ion implantation (FIG. 2A) and a sample without Ni ion implantation (FIG. 2B), which are taken after annealing them with energy of 300 mJ/cm²;

FIGS. 3A and 3B are TEM photographs of cross-sectionals of a sample with Ni ion implantation (FIG. 3A) and a sample without Ni ion implantation (FIG. 3B), which are taken after annealing them with energy of 500 mJ/cm²;

FIGS. 4A and 4B are TEM photographs of cross-sectionals of a sample with Ni ion implantation (FIG. 4A) and a sample without Ni ion implantation (FIG. 4B), which are taken after annealing them with energy of 600 mJ/cm²;

FIGS. 5A and 5B are transmission electron diffraction (TED) photographs of a sample with Ni ion implantation (FIG. 5A) and a sample without Ni ion implantation (FIG. 5B), which are taken after annealing them with energy of 300 mJ/cm²;

FIGS. 6A and 6B are TED photographs of a sample with Ni ion implantation (FIG. 6A) and a sample without Ni ion implantation (FIG. 6B), which are taken after annealing them with energy of 500 mJ/cm²;

FIGS. 7A and 7B are TED photographs of a sample with Ni ion implantation (FIG. 7A) and a sample without Ni ion implantation (FIG. 7B), which are taken after annealing them with energy of 600 mJ/cm²; and

FIG. 8 illustrates the result of measuring RMS of surfaces of a sample with Ni ion implantation and a sample without Ni ion implantation using AFM with respect of annealing energy.

### DETAILED DESCRIPTION OF EXEMPLARY EMBODIMENTS OF THE INVENTION

Hereinafter, a method of crystallizing an amorphous Si film according to an exemplary embodiment of the present invention will be described in more detail with reference to the attached drawings.

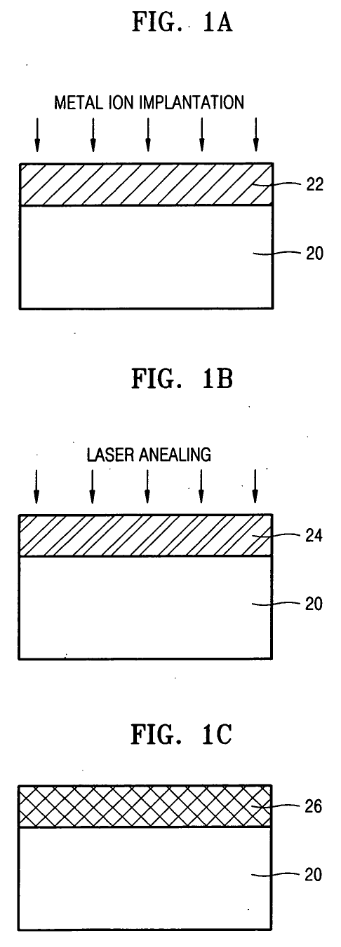

FIGS. 1A through 1C are a process flow chart illustrating a method of crystallizing an amorphous Si film according to the present invention.

Referring to FIGS. 1A through 1C together, an amorphous Si film 22 formed on a substrate 20 may be first doped with predetermined metal ions to obtain an amorphous Si film 24 doped with metal ions.

The substrate may be any one of an amorphous Si, glass, sapphire glass, MgO, diamond, and GaN substrates.

The metal may be at least one of Ag, Au, Al, Cu, Cr, Co, Ni, Ti, Sb, V, Mo, Ta, Nb, Ru, W, Pt, Pd, Zn, and Mg. Thus, these metals may be used alone or in a combination.

The metal ions may be doped in an amount of 1×10¹⁰ atoms/cm² to 1×10¹⁷ atoms/cm².

The doping of the metal ions may be performed using an ion implantation apparatus and doping energy of metal ions may be in a range of 1-1000 keV.

According to another embodiment of the present invention, the doping of the metal ions may also be performed using another ion doping apparatus known in the art.

Then, the amorphous Si film 24 doped with metal ions may be annealed with laser beam. In the annealing operation, the amorphous Si film 24 may be crystallized, thereby obtaining a crystallized Si film 26.

The amorphous Si film 24 doped with metal ions may be crystallized with a ower energy density of laser beam compared to an amorphous Si film that is not doped with metal ions. This may be supported by a laser absorption coefficient and a catalytic effect of metal ions.

Generally, in the case of laser annealing, a degree of crystallizing an amorphous Si may be largely dependent on the laser absorption coefficient of an amorphous Si.

The metal ions doped in the amorphous Si film 24 may increase the laser absorption coefficient of the amorphous Si. Thus, the amorphous Si film 24 absorbs more laser energy when being annealed with a laser beam.

Also, the metal ions doped in the amorphous Si film 24 may act as a catalyst capable of promoting a crystallization of an amorphous Si when being annealed.

Thus, it is possible to crystallize the amorphous Si film 24 with a laser beam of low energy, and a Si film crystallized with low laser beam energy can have improved surface roughness.

The energy density of a laser beam may be in a range of 50-3000 mJ/cm². The energy density of a laser beam may be in a range of 300-800 mJ/cm².

According to another embodiment of the present invention, the annealing may also be performed using another apparatus having a heater.

According to the method of crystallizing an amorphous Si film of the present invention, the amorphous Si film may be crystallized with lower energy. Also, due to the use of a laser beam of lower energy, the surface roughness of a crystallized Si film can be improved.

According to the method of crystallizing an amorphous Si film of the present invention, the amorphous Si film can be uniformly crystallized from the surface to a certain thickness. This is because it is possible to dope the amorphous Si film to a predetermined thickness with metal ions using an ion implantation apparatus. The thickness doped may be determined by ion implantation energy.

The effect of uniform crystallization may be compared with the disadvantages that there is a considerable amount of Ni silicide in a crystallized portion and that crystallization occurs only on a surface portion contacting Ni-silicide as disclosed in U.S. Pat. No. 6,479,329 B2.

In particular, when applying the method of crystallizing an amorphous Si film of the present invention to active matrix liquid crystal displays (AMLCDs), semiconductor memory devices, and next-generation devices, high quality devices can be effectively fabricated and performances of a device are increased, thereby improving product competitiveness.

### EXAMPLE

In this Example, a sample having an amorphous Si film formed on a Si substrate was first prepared. Then, implantation of Ni ions was performed on the amorphous Si film with energy of 25 keV in a dose of 1×10¹⁵ atoms/cm².

Then, the sample with Ni implantation was loaded in a vacuum chamber, and then annealed using an excimer laser beam while retaining a vacuum of about 10⁻³ torr.

In this Example, a KrF excimer laser beam was used and energy density of laser beam was in the range of 300-700 mJ/cm².

To verify the effects of Ni ion implantation, a sample without a Ni ion implantation was prepared and annealed under the same conditions as described above and compared with the sample with the Ni ion implantation.

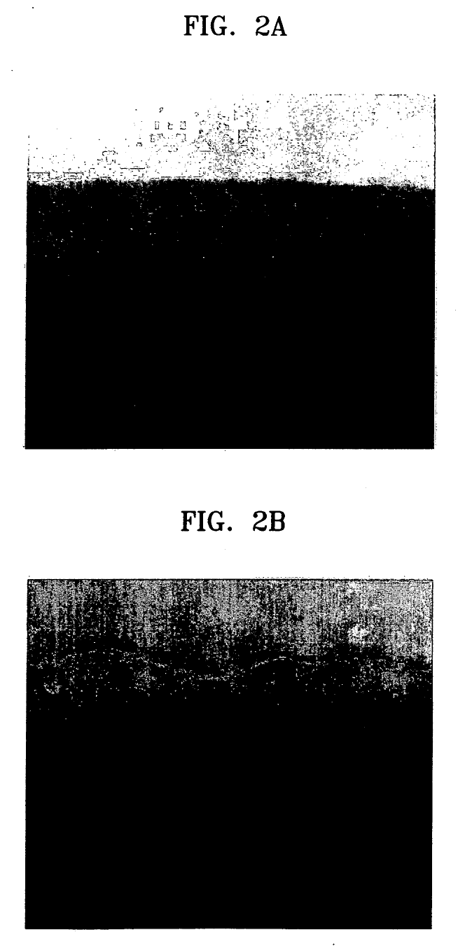

FIGS. 2A and 2B are transmission electron microscope (TEM) photographs of cross-sectionals of the sample with the Ni ion implantation (FIG. 2A) and the sample without the Ni ion implantation (FIG. 2B), which were taken after annealing them with 300 mJ/cm².

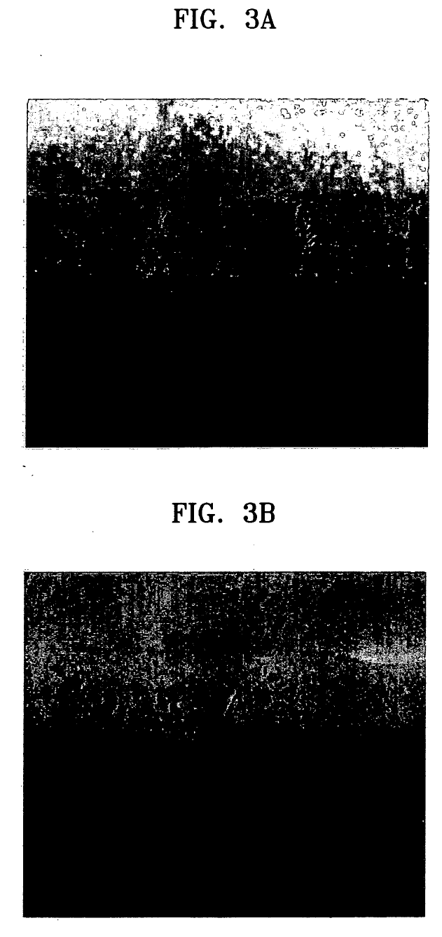

FIGS. 3A and 3B are TEM photographs of cross-sectionals of the sample with the Ni ion implantation (FIG. 3A) and the sample without the Ni ion implantation (FIG. 3B), which were taken after annealing them with 500 mJ/cm².

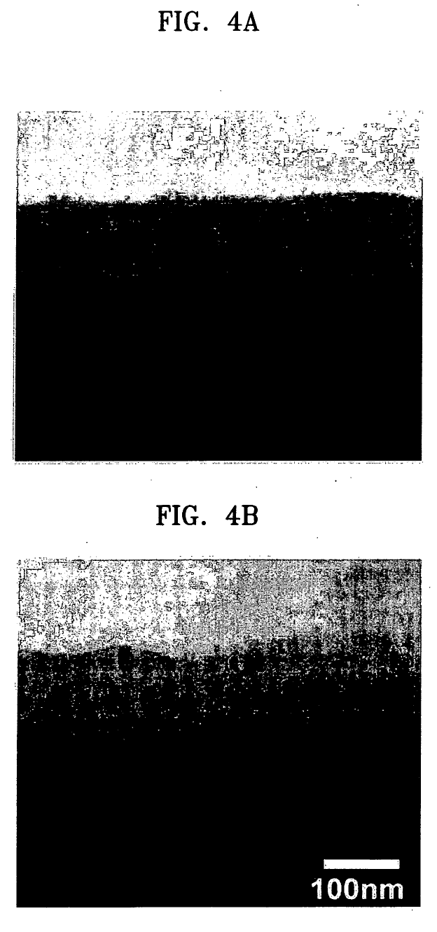

FIGS. 4A and 4B are TEM photographs of cross-sectionals of the sample with the Ni ion implantation (FIG. 4A) and the sample without the Ni ion implantation (FIG. 4B), which were taken after annealing them with 600 mJ/cm².

Referring to FIGS. 2A, 2B, 3A, 3B, 4A, and 4B together, it can be observed that as laser energy density increases, an amorphous Si film is crystallized.

It can be seen that in the case of the samples with the Ni ion implantation (FIGS. 2A, 3A, 4A), as laser energy density increases, the surface roughness of the samples is improved. On the contrary, the samples without Ni ion implantation (FIGS. 2B, 3B, 4B) have a deteriorated surface roughness.

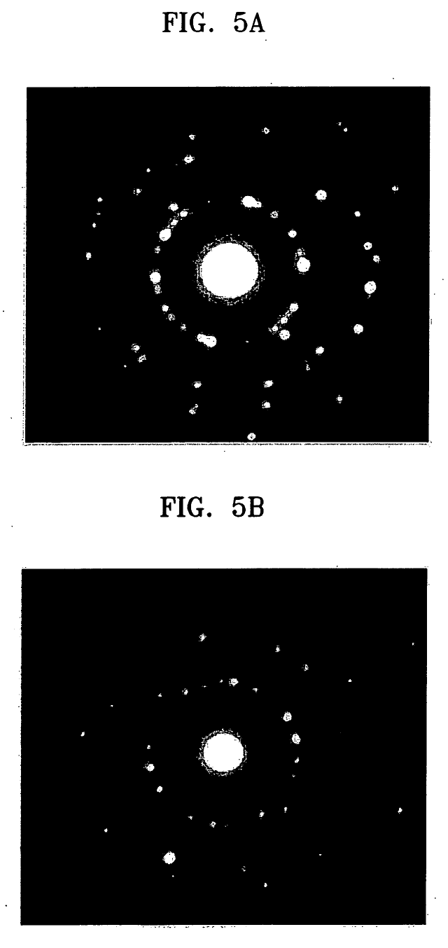

FIGS. 5A and 5B are transmission electron diffraction (TED) photographs of a sample with the Ni ion implantation (FIG. 5A) and a sample without Ni ion implantation (FIG. 5B), which were taken after annealing them with 300 mJ/cm².

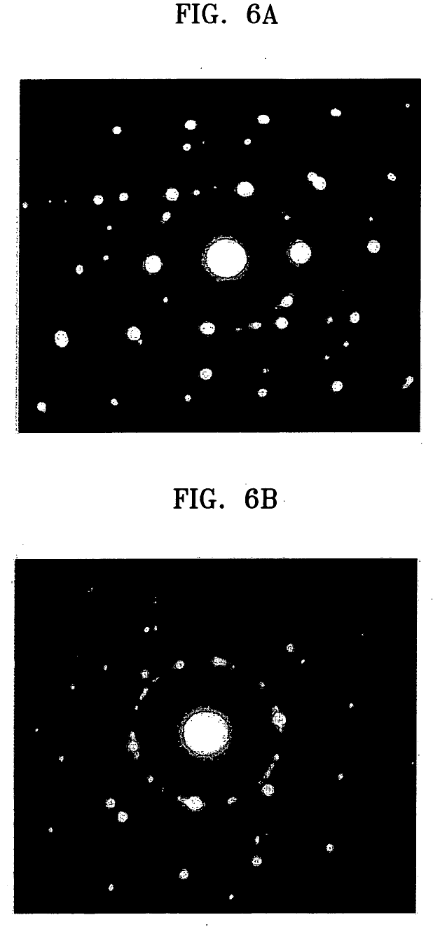

FIGS. 6A and 6B are TED photographs of a sample with the Ni ion implantation (FIG. 6A) and a sample without the Ni ion implantation (FIG. 6B), which were taken after annealing them with 500 mJ/cm².

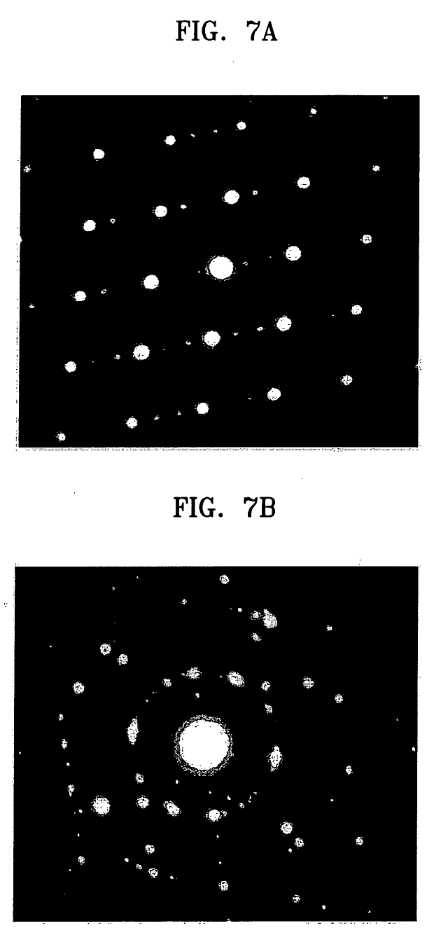

FIGS. 7A and 7B are TED photographs of a sample with the Ni ion implantation (FIG. 7A) and a sample without Ni ion implantation (FIG. 7B), which were taken after annealing them with 600 mJ/cm².

Referring to FIGS. 5A, 5B, 6A, 6B, 7A, and 7B together, the samples with the Ni ion implantation (FIGS. 5A, 6A, 7A) starts the crystallization of the amorphous Si film at 300 mJ/cm². As the energy density increases, the amorphous Si is gradually crystallized and the entire amorphous Si film is crystallized at 600 mJ/cm².

However, the samples without the Ni ion implantation (FIGS. 5B, 6B, 7B) have lower degrees of crystallization compared to the samples with the Ni ion implantation (FIGS. 5A, 6A, 7A).

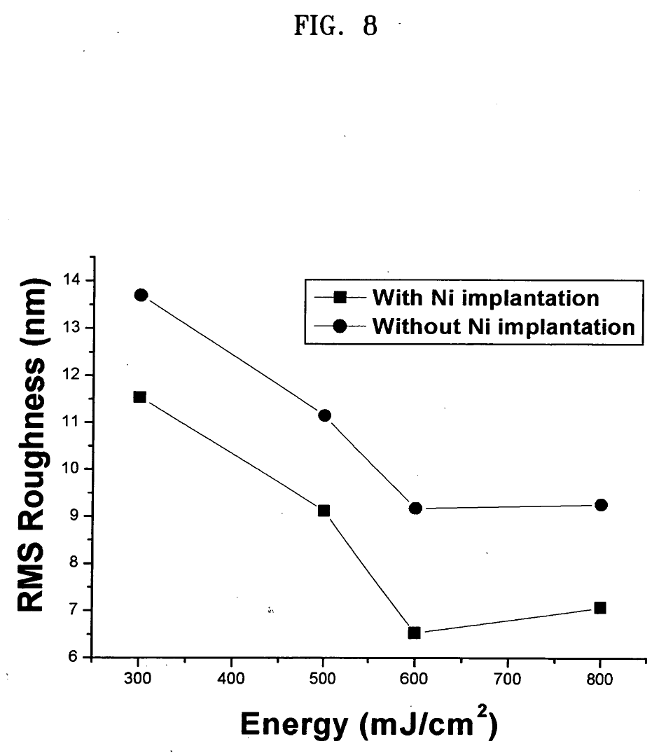

FIG. 8 illustrates the result of measuring the root mean square (RMS) of the surfaces of a sample with the Ni ion implantation and a sample without Ni ion implantation using an AFM with respect to the annealing energy.

In both samples, it can be observed that as the energy density increases to 600 mJ/cm², RMS roughness decreases, but RMS roughness increases at energy density of 600 mJ/cm² or greater.

In the entire range of energy density, the surface of the sample with the Ni ion implantation has less RMS roughness compared to the surface of the sample without the Ni ion implantation.

Carrier mobilities of the sample with Ni ion implantation and the sample without Ni ion implantation, measured after annealing them at 600 mJ/cm² were 49.4 cm²/V·s and 10.2 cm²/V·s, respectively.

This result indicates that a degree of crystallization of the sample with the Ni ion implantation is better than that of the sample without the Ni ion implantation.

That is, when fabricating LCD devices using the method of crystallizing an amorphous Si film according to the present invention, devices having high carrier mobility can be obtained.

According to the method of crystallizing an amorphous Si film of the present invention, the amorphous Si film can be crystallized with lower energy and the surface roughness of a crystallized Si film can be improved.

Also, according to the method of crystallizing an amorphous Si film of the present invention, the amorphous Si film can be uniformly crystallized from the surface to a certain thickness.

In particular, when applying the method of crystallizing an amorphous Si film of the present invention to active matrix liquid crystal displays (AMLCDs), semiconductor memory devices, and next-generation devices, high quality devices can be effectively fabricated and performances of a device are maximized, thereby improving product competitiveness.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of crystallizing an amorphous Si film, the method comprising:
doping the amorphous Si film formed on a substrate with predetermined metal ions; and
annealing the amorphous Si film doped with the metal ions to crystallize the amorphous Si film.

2. The method of claim 1, wherein the metal is at least one selected from the group consisting of Ag, Au, Al, Cu, Cr, Co, Ni, Ti, Sb, V, Mo, Ta, Nb, Ru, W, Pt, Pd, Zn, and Mg.

3. The method of claim 1, wherein the metal ions are doped in an amount of 1×10¹⁰ atoms/cm² to 1×10¹⁷ atoms/cm².

4. The method of claim 1, wherein an amount of doping energy of the metal ions is in a range of 1-1000 keV.

5. The method of claim 1, wherein the annealing is performed using a laser beam.

6. The method of claim 5, wherein energy density of the laser beam is in the range of 50-3000 mJ/cm².

7. The method of claim 6, wherein energy density of the laser beam is in the range of 300-800 mJ/cm².

8. The method of claim 1, wherein the substrate is any one selected from the group consisting of an amorphous Si, glass, sapphire glass, MgO, diamond, and GaN substrates.

9. The method of claim 1, wherein the doping of the metal ions is performed using an ion implantation apparatus.
